(19) United States
(12) Patent Application Publication
(10) Pub. No.: US 2025/0324815 A1
(43) Pub. Date: Oct. 16, 2025

(54) REAR JUNCTION BIFACIAL POLY-SI/SIOX PASSIVATED CONTACT SOLAR CELLS AND METHOD OF MANUFACTURING THE SAME

(71) Applicant: GEORGIA TECH RESEARCH CORPORATION, Atlanta, GA (US)

(72) Inventors: Ajeet ROHATGI, Atlanta, GA (US); Young-Woo OK, Atlanta, GA (US); Sagnik DASGUPTA, Atlanta, GA (US); Vijaykumar D. UPADHYAYA, Atlanta, GA (US); Wook-Jin CHOI, Atlanta, GA (US); Ajay D. UPADHYAYA, Atlanta, GA (US); Aditi JAIN, Atlanta, GA (US)

(21) Appl. No.: 18/870,171

(22) PCT Filed: May 31, 2023
(86) PCT No.: PCT/US2023/023992

§ 371 Date: Nov. 27, 2024

Related U.S. Application Data
(60) Provisional application No. 63/347,436, filed on May 31, 2022.
(60) Provisional application No. 63/347,445, filed on May 31, 2022.

(51) Int. Cl. H10F 77/30; H10F 71/00; H10F 77/20

(52) U.S. Cl. CPC H10F 77/311; H10F 71/128; H10F 77/215

(57) ABSTRACT

Disclosed is a highly efficient rear junction Tunnel oxide passivated contact (TOPCon) solar cell photovoltaic cell with TOPCon on both sides. Further disclosed are laser etching and screen printing methods for patterning the TOPCon. —Further disclosed is a tandem cell having a TOPCon cell as a bottom cell. Low-cost, manufacturable screen printed TOPCon on both sides of a solar cell to exploit the full potential of this technology and concept. The TOPCon can be fabricated on the front side to be selectively placed under a metal grid with 5% area coverage, while the remaining 95% area on the front has an undiffused Si wafer passivated with AI2O3/SiN dielectric.

This application is a non-provisional of and claims priority benefit of U.S. Provisional Application Ser. No. 63/347,436, filed May 31, 2022, pending, and U.S. Provisional Application Ser. No. 63/347,445, filed May 31, 2022, pending, which applications are hereby incorporated by this reference in their entireties.

### GOVERNMENT LICENSE RIGHTS

This invention was made with government support under grant number GR00010248 awarded by the Department of Energy—Office of Energy Efficiency and Renewable Energy (EERE) under the Solar Energy Technologies Office (SETO). The government has certain rights in the invention.

This material is based upon work supported by the U.S. Department of Energy's Office of Energy Efficiency and Renewable Energy (EERE) under Solar Energy Technologies Office (SETO) Agreement Number DE-EE0009350, DE-EE0008562, and DE-EE0008975.

### BACKGROUND

### Acknowledgements

### Background

The solar cell is an important component of the PV hardware chain because its cost, efficiency, lifetime, and annual degradation rate have a major impact on the cost of electricity (LCOE). Apart from high-cost, high-efficiency SunPower's Interdigitated Back Contact (IBC) and Panasonic's Heterojunction with Intrinsic Thin-layer (HIT) cells, the disclosed double side tunnel oxide passivated poly-Si/SiOₓ contact (TOPCon) is the only other Si technology today that can achieve ≥25% efficiency but at a cost that is even lower than the most widely produced lower-cost 21-22% passivated emitter rear contact (PERC) cells.

All current high-performance cells (>25%) are too expensive due to process complexity, the number of processing steps, expensive metallization schemes, and high capex while the lower-cost cells are not efficient enough (<22%) due to diffusion and metal-induced recombination in Si absorber to reach the LCOE target of ≤3¢/kWh, which is a factor of two lower than fossil fuels. This target requires 25% efficient modules at ˜25 ¢/W.

Poly-Si-based passivated contact technology offers a solution to reducing diffusion- and metal contact-induced recombination losses in bulk Si.

However, so far it has primarily been confined to the rear side of a solar cell because of high parasitic absorption losses in the poly-Si and the inability to make good, screen-printed contacts to very thin front poly-Si layers without compromising passivation quality and J₀.

### SUMMARY

In this disclosure, a novel and industry-feasible approach is provided to deploy low-cost, manufacturable screen printed TOPCon on both sides of a solar cell to exploit the full potential of this technology and concept. The TOPCon can be fabricated on the front side to be selectively placed under a metal grid with ˜5% area coverage, while the remaining 95% area on the front has an undiffused Si wafer passivated with Al₂O₃/SiN dielectric. This will provide almost as good a passivation as full area TOPCon without appreciable absorption of light. This will give as good a Voc as full area DSTOPCon without compromising Short circuit current density. In addition, it will allow the use of thick TOPCon (˜200 nm), eliminating the risk of contact punching or shunting due to screen-printed contacts to thin poly.

In addition to the concept and efficiency potential of this design, the instant disclosure also provides a novel way to form double side TOPCon in a simple and rapid way.

The instant disclosure also discloses a very innovative way of patterning front TOPCon by selective area laser oxidation. The instant design and process sequence is expected to not only enhance the efficiency, but also to reduce the cell processing cost by eliminating traditional diffusion technology. The modelling, design, and fabrication sequence are commercially ready for fully screen printed ≥25% bifacial double side selective TOPCon cells.

To the best of knowledge of the inventors, this method of forming double side selective TOPCon has never been done before. In addition, the disclosed cell structure is bifacial with a much lower temperature coefficient that can further increase energy harvesting and lower LCOE. Finally, most PERC manufacturing lines today can be easily transformed into TOPCon lines by adding the poly-Si deposition tools, enabling the rapid and low-cost adaptation/transfer of this technology.

In another aspect, a DS-TOPCon cell design is disclosed with selective poly-Si contacts on the front, only below metal contacts. The TOPCon area coverage on the front is only ˜5% to prevent absorption in poly-Si. The remaining 95% area is a bare Si wafer coated with Al₂O₃/SiN coating, which provides excellent passivation. This resulted in J₀ or Voc comparable to full area DS-TOPCon but with no appreciable absorption in front poly-Si. It also allows the use of thick poly-Si on front without risking the J₀ degradation due to screen-printed contacts. Modelling shows this cell structure can produce 25% cells at a low-cost.

In another aspect, an experimental formation is also disclosed of a low-cost DS-TOPCon precursor using only one high-temperature step without masking steps. In this process, Boron (B) is diffused in the back intrinsic poly using BSG glass, and Phosphorus (P) is diffused on the front intrinsic poly by POCL₃ diffusion during the same high-temperature cycle without any cross doping. It is demonstrated that this unique, low-cost process gives excellent J₀ and iv_{oc} values consistent with 25% efficiency.

Another aspect of the disclosure involves patterning of front poly by selective UV laser oxidation, followed by KOH etching of poly. A 1-4 nm laser-grown oxide was found to be sufficient for masking KOH etching, resulting in well-defined polyfingers. Screen-printed contacts are formed on top of these poly fingers by firing through a SiN coating. It is shown herein that SiN deposition restores the laser-induced degradation of J₀. This unique process was successfully demonstrated.

The exemplary system and method may be employed for silicon cell manufacturing. Solar cell manufacturers can employ equipment such as LPCVD or PECVD to their TOPCon production lines for such silicon cell fabrication.

### BRIEF DESCRIPTION OF THE DRAWINGS

The accompanying figures, which are incorporated herein and form part of the specification, illustrate Poly-Si/SiOx passivated contact solar cells and method of making the same. Together with the description, the figures further serve to explain the principles of the Poly-Si/SiOx passivated contact solar cells and method of making the same described herein and thereby enable a person skilled in the pertinent art to make and use the Poly-Si/SiOx passivated contact solar cells and method of making the same.

FIG. 1 illustrates an example DS-TOPCon cell structure and efficiency.

FIG. 2 shows computer modeling parameters for a DS-TOPCon cell according to principles described herein.

FIG. 3 illustrates an advantage of an exemplary rear junction cell over the traditional front junction cell.

FIG. 4 shows a simulated technology roadmap developed for proposed DS-TOPCon cell according to principles described herein.

FIG. 5 illustrates development of Recipe for ex-situ doped n- and p-TOPCon using APCVD B glass and POCl₃ diffusion.

FIG. 6 illustrates a process sequence for co-diffused DS-TOPCon structure and final cell precursor.

FIG. 7 illustrates selective laser oxidation technology for pattering poly-Si fingers according to principles described herein.

FIG. 8 shows a demonstration of Oxide Growth using UV laser—subpart 8(a), shows passivation quality after SiNx, subpart 8(b) shows a simulated firing process, and subpart 8(c) shows pattering ability of the oxide mask.

FIG. 9 shows another example DS-TOPCon Cell Structure and Efficiency

FIG. 10 computer modeling parameters for a DS-TOPCon cell according to principles described herein.

FIG. 11 shows the advantage of the exemplary rear junction cell over the traditional front junction cell.

FIG. 12 shows a simulated technology roadmap developed for proposed DS-TOPCon Cell according to principles described herein.

FIG. 13 shows a cell structure and process flow, and cell performance with 35 nm n-TOPCon according to principles described herein.

FIG. 14 illustrates process flow of DS-TOPCon precursor (left) and cross-sectional schematic diagrams of DS-TOPCon precursor in process (right) according to principles described herein.

FIG. 15 illustrates development of receipt for ex-situ Doped N- and P-TopCon using APCVD B glass and POCL₃ diffusion.

FIG. 16 shows the measured iV_{oc} and iFF of finished DS-TOPCon precursor with there different pre-annealing temperatures.

FIG. 17 shows a comparison of etching rate between n-poly-Si and p-poly-Si.

FIG. 18 shows a comparison of etching rate between n-poly-Si and p-poly-Si.

FIG. 19 shows schematic images from symmetric DS-TOPCon to asymmetric n-TOPCon with ˜200 nm p-TOPCon on back and only ˜20 nm textured n-poly on front after selective etching.

FIG. 20 is a schematic diagram illustrating a selective DS-TOPCon solar cell featuring patterned front iOx/n+ poly-Si and rear iOx/p+ poly-Si.

FIGS. 21(a)-(d) are schematic diagrams of symmetric test structures;

FIG. 21(e) shows a summary of measured J₀ before and after high temperature firing

FIG. 22 shows simulated cell efficiency of RJ selective DS-TOPCon cell structure as a function of front J₀, field.

FIG. 23 is a schematic of another cell structure according to principles described herein.

FIG. 24 is a schematic of a fabricated cell structure.

FIG. 25 shows a Quokka 2 simulation of the effect of poly-finger width and thickness on cell efficiency.

FIG. 26 is a plan view scanning electron micrograph showing obtained widths of laser marked lines.

FIG. 27(a) is a plan view photograph of a laser patterned sample capped with silicon nitride showing multiple poly-fingers and a busbar. FIG. 27(b) is cross-section image of a single texturing pyramid in the field region. FIG. 27(c) is a rounded pyramid in the poly-finger region showing presence of Poly-Si after KOH etching.

FIG. 28 shows an ECV active dopant profile of phosphorus in the front n poly-Si.

### DETAILED DESCRIPTION

To facilitate an understanding of the principles and features of various embodiments of the present invention, they are explained hereinafter with reference to their implementation in illustrative embodiments.

A DS-TOPCon cell design is first disclosed with selective poly-Si contacts on the front, only below the metal contacts. The TOPCon area coverage on the front may be only ˜5% to prevent absorption in poly-Si. The remaining 95% area may be a bare Si wafer coated with Al₂O₃/SiN coating, which provides as good passivation, like TOPCon. This resulted in J₀ or Voc comparable to full area DS-TOPCon but with no appreciable absorption in front poly-Si. It also allows the use of thick poly on the front without risking the J₀ degradation due to screen-printed contacts. The modeling shows this cell structure can produce ≥25% efficiency cells. Parameters to achieve an approximately >25% cell efficiency may be specified by detailed computer modeling. One advantage of the presently disclosed devices and methods of manufacturing is lowered production costs, but such is not the only motivation, advantage or innovation. Cell efficiency and streamlined production are significant advantages over prior devices and methods.

Experimental formation of a low-cost DS-TOPCon precursor is described herein using only one high-temperature step and no masking steps. In this process B is diffused into the back intrinsic poly using boronsilicate glass (BSG) and Phosphorus P is diffused into the front intrinsic poly by POCL₃ diffusion during the same high-temperature cycle without any cross doping. We demonstrated that this low-cost process also gives excellent J₀ and implied Voc values consistent with 25% efficiency.

Patterning of front poly is demonstrated by selective UV laser oxidation, followed by KOH etching of poly. A 1-4 nm laser-grown oxide was found to be sufficient for masking during the KOH etching, resulting in well-defined poly-Si fingers. Screen-printed contacts are formed on top of these poly fingers by firing through a SiN coating. It was shown that SiN deposition restores the laser-induced degradation of J₀. This unique process was successfully demonstrated.

Examples of various cell structures according to principles described herein are provided throughout this specification.

### Example #1: Cell Structure, Modelling and Design to Attain Screen Printed 25% Efficiency Bifacial Selective Area DS-TOPCon Cell

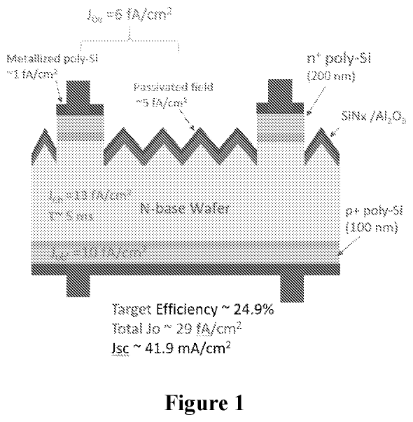

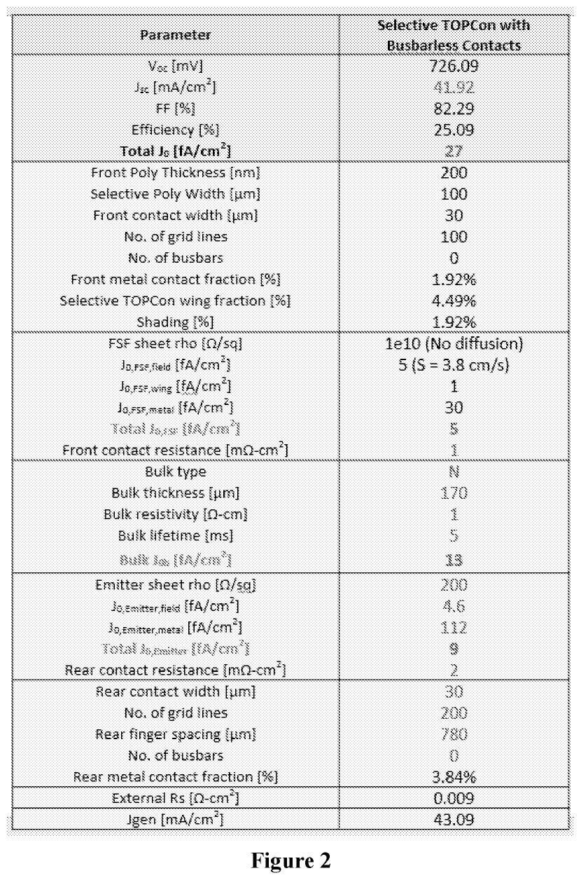

The concepts, detailed computer modeling, and understanding of example solar cells as provided herein are summarized in FIGS. 1-4, which show that the proposed selective area double side TOPCon cell structure with rear junction design on n-base Si can produce ˜25% efficiency at a low-cost. Figure land 2 show that the proposed cell structure with 100-200 nm full area p-TOPCon on the rear and ˜100-200 nm textured selective area n-TOPCon underneath the metal grid on the front with screen-printed contacts on both sides can produce ˜25% efficiency. Modeling in FIG. 2 shows that this can use total recombination current J₀ of 27 fA/cm², with 5 fA/cm² coming from the front side n-TOPCon, 13 fA/cm² from bulk Si, and 9 fA/cm² from the rear p-TOPCon. These are quite achievable using DS-TOPCon concept and n-base solar cell.

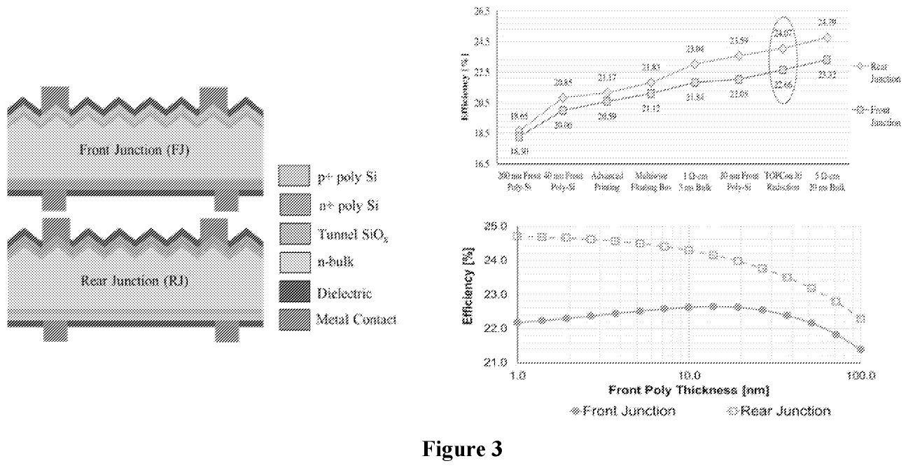

Detailed modeling in FIG. 2 also reveals a list of all the practically achievable parameters to achieve ˜25% efficiency with this cell design, although the parameters may be varied without departing from the spirit and scope of the invention. In fact, most material parameters for each layer have already been achieved in our lab. The technologies used may be conducive to mass production at a low cost. The design feature involves a rear junction formed with p-TOPCon on n-Si on the backside. FIG. 3 shows the advantage of an exemplary rear junction cell over the traditional front junction cell. Note that the front junction design will prevent the use of thinner poly-Si to avoid significant absorption and resistive losses in the front poly-Si layer. However, in a rear junction device, efficiency becomes insensitive to the thickness and sheet resistance of front n-poly Si, without any penalty in carrier transport and collection of electrons on the front of the device. FIG. 3 shows that the rear junction device can produce, perhaps, >1% higher efficiency than a front junction device.

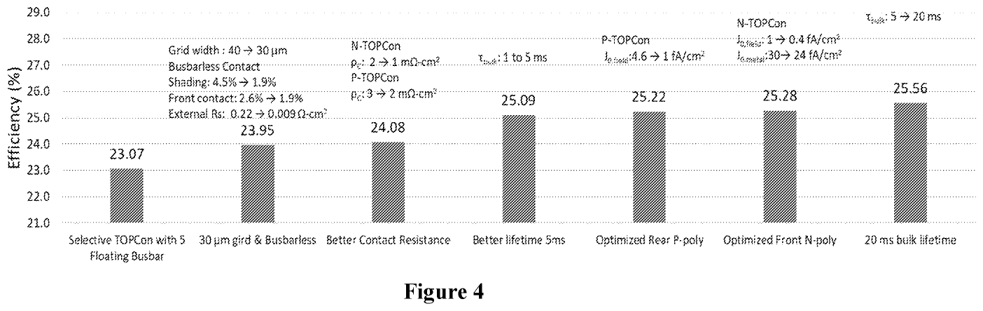

FIG. 4 gives a step-by-step technology roadmap to achieve approximately ≥25% efficiency from this cell design by quantifying the benefit of each proposed technology enhancement and innovation.

Thus, the disclosed structure and modeling can potentially achieve; ≥25% efficiency in a cell design. Accordingly, the present disclosure describes systems and methods to (1) Develop n+ and p+ doped poly-Si/SiOx contact layers with metalized recombination current density (J₀) of <10 fA/cm²; (2) Reduce bulk defects, optimize lifetime (>3 ms) and resistivity to achieve J₀ bulk of ˜10 fA/cm²; (3) reduce parasitic absorption by depositing selective area thick TOPCon under the metal grid with ˜5% coverage and no diffusion in between the grid lines on the front; (4) Develop advanced screen-printing paste and firing conditions to make ohmic contacts to −200 nm poly-Si without compromising J₀ and fill-factor (FF>82.5%); and (5) Implement back junction cell design to desensitize the cell performance with respect to the front poly sheet resistance.

Modeling described herein demonstrates that fabrication of low-cost double side selective area TOPCon back junction (n+−n−p+) cell with the design and material parameters above can produce low-cost fully screen-printed bifacial cells with Voc ˜726 mV, Jsc ˜42 mA/cm², FF ˜0.82 and η ˜25%.

### Example #2. Process to Fabricate High-Quality Double Side TOPCon Prior to Patterning the Front Side

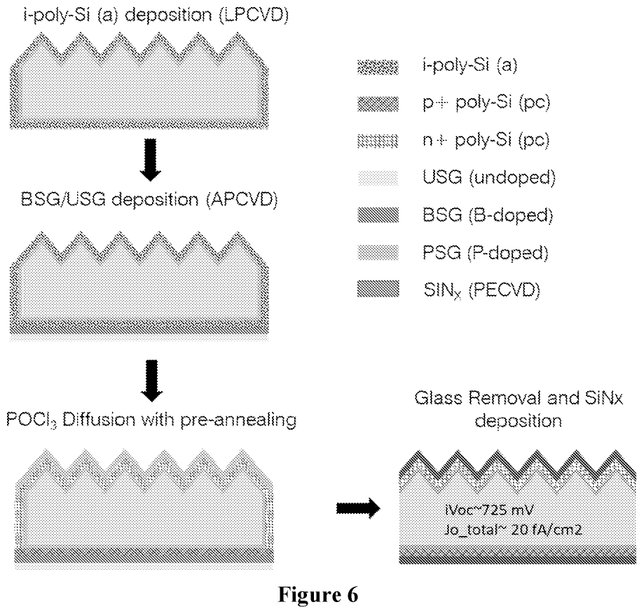

Besides the proposed cell design, modelling, and efficiency potential of this cell structure, provided is a novel way to produce a low-cost DS-TOPCon precursor. This involves growing a 100-200 nm undoped intrinsic i-poly-Si layer on top of a tunnel oxide on both sides of the wafer by LPCVD (low-pressure chemical vapor deposition) at ˜580° C. As demonstrated, ˜15 Å thick tunnel oxide is grown by chemical oxidation of Si in HNO₃ at ˜100° C. prior to LPCVD of intrinsic poly on both sides. Next, we deposit APCVD grown borosilicate glass (BSG) is deposited only on the backside and then capped with APCVD grown thick SiOx (FIG. 6). This sample is then heat-treated for 30 min in a POCL₃ ambient in a tube furnace to form n-TOPCon on the front at 850° C. by diffusing P into the intrinsic front poly-Si. Note that Phosphorus diffusion on the back is blocked by thick APCVD SiOx on the rear side. We found that 850° C. is not sufficient to drive enough B from APCVD BSG on the backside. ˜950° C./30 min heat treatment may be applied to achieve desired sheet resistance of ˜150 ohms/.

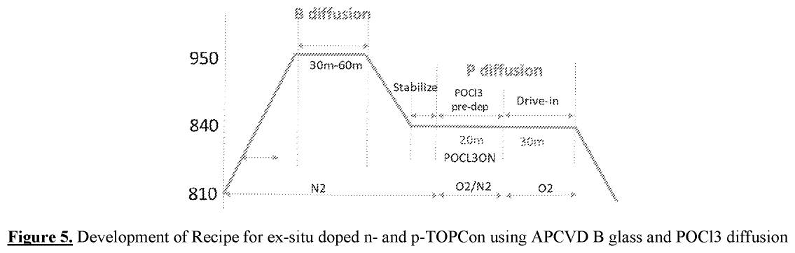

This led to the development of a heat treatment profile shown in FIG. 5 involving ˜950° C./1 hour heat treatment in N2 first to drive sufficient B on the backside followed by lowering the temp to 840° C. followed by POCl₃ diffusion for 30 min to form n-TOPCon during the same thermal cycle. Thus, in a single high temperature step, both n and p type TOPCons are formed without any auto doping or cross diffusion due to the presence of thick oxide on the back. Thick oxide not only blocks P diffusion on the backside but also prevents B from diffusing out onto the front side. Thus, there are no masking steps required, which makes the process very simple, elegant, and inexpensive. FIG. 6 shows that a DS-TOPCon precursor formed by this unique process resulted in an excellent J₀ value of ˜20 fA/cm² with an implied Voc of 725 mV, appropriate for a 25% efficiency cell.

### Example #3: Low-Cost Process to Pattern Poly-Si to Form Selective Front TOPCon for DS-TOPCon Cell Fabrication

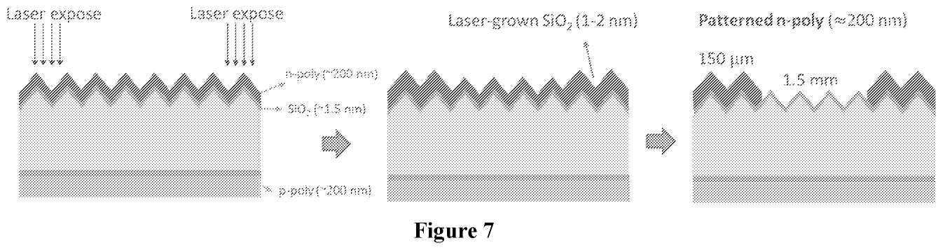

This section describes a method to form selective n-TOPCon on front. FIG. 7 shows that this concept uses a UV laser (530 nm) of appropriate power to rapidly oxidize poly-Si with a thickness of 1-4 nm, which is sufficient to mask poly-Si during etching in dilute KOH solution.

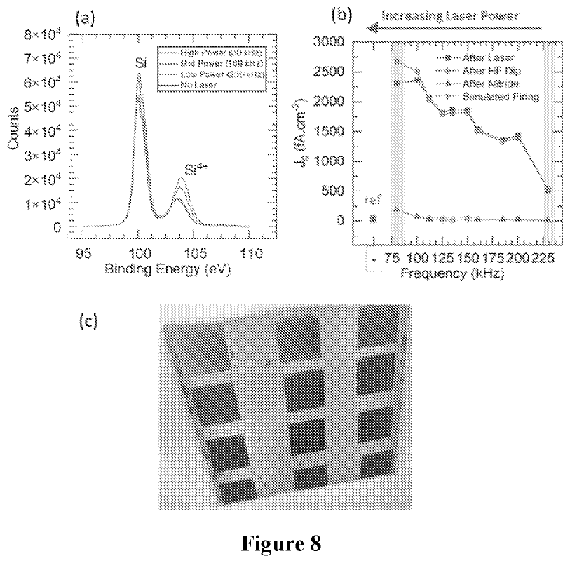

A study has successfully demonstrated both the oxidation and masking operations. In addition, the study found that after laser oxidation, the J₀ of TOPCon is degraded appreciably. However, when the study coat the poly-Si with a nitrite coating for screen print firing, the degraded J₀ or TOPCon passivation is restored dramatically to a level appropriate for ˜25% cells. These results are shown in FIG. 8. To our knowledge, this has never been done for solar cell applications.

### Experimental Results and Examples

Additional experimental results and examples are provided herein in Appendix An and Appendix B, each of which is incorporated by reference herein in its entirety.

### Discussion

Compared to the 19-22% efficient lower cost full Al-BSF and PERC cells, which account for ˜95% of the market share today, double side TOPCon cells can achieve much higher efficiency (˜25%) because all the doped and metalized regions are displaced outside the Si absorber. On the other hand, compared to the current ≥25% HIT and IBC cells, the disclosed TOPCon cell technology is very simple with low capex because of the inexpensive metallization and elimination of all the processing steps that are often used to remove, pattern, or etch deposited layers. The disclosed low-cost double side TOPCon cell can open the pathways for low-cost Si/perovskite type tandem solar cells with an efficiency potential of over 30%.

Poly-Si/SiOₓ carrier selective passivating contacts are an ideal candidate for next-generation solar cells because heavily doped regions, as well as metal contacts, are physically decoupled from the Si substrate via an ultra-thin tunnel oxide (≤15 Å, similar to the role of intrinsic a-Si layer in the >25% efficient HIT cells). However, poly-Si/SiOₓ contacts are much more thermally stable than a-Si-based HIT contacts and can withstand high firing temperatures (>700° C.) required for the lowest-cost high-throughput screen-printed contacts. When n⁺ poly-Si is deposited on top of tunnel oxide, it becomes electron selective contact (n-TOPCon) and vice versa for p-TOPCon. This is because heavily doped n⁺-poly-Si on top of tunnel oxide accumulates electrons and repels the minority carrier holes at the tunnel oxide/n-Si interface due to appropriate n⁺−n band bending. These electrons are easily able to tunnel through the oxide from n-Si into the n⁺-poly while holes are blocked from entering the n⁺ poly, making it an electron selective contact and virtually eliminating hole recombination in the n⁺ region and metal contact. Similarly, p-TOPCon allows only the holes to tunnel through, making it a hole selective contact and reducing the electron recombination in the p⁺ region and metal contact. The interface recombination at the tunnel oxide-Si interface defects is also reduced due to the presence of an accumulation layer. Because of this dramatic reduction of minority carrier recombination in the heavily doped regions, metal contacts, and interface, extremely low J₀ values (<5 fA/cm²) and high cell efficiency can be achieved.

Several groups have reported efficiencies exceeding 25% on laboratory-scale TOPCon cells employing single side poly-Si based passivated contacts (Fraunhofer ISE and ISFH). Two cell manufacturers, Trina Solar and Jolywood, have started pilot production of single side n-TOPCon cells with an efficiency of ˜22.5%. Some prominent examples of high-efficiency R&D cells with passivated contacts in the literature include 26.7% Si heterojunction IBC cells by Kaneka (Yoshikawa et al. Nature Energy 2017), 25.2% tunnel layer passivated IBC cell by SunPower (Smith et al. IEEE PVSC 2016), 26.1% poly-Si on oxide (POLO) IBC cell by ISFH (Haase et al. Solmat 2018), and 25.7% single side rear n-TOPCon cell by Fraunhofer ISE (Richter et al. Solmat 2017) with conventional B diffusion on the front, evaporated and photolithography contacts. The ˜26% TOPCon cells were realized on a small area (<16 cm²) with non-manufacturable technologies, but they provide the existence proof of the potential of this concept for achieving very high efficiency even with a single side TOPCon.

Even though Poly-Si based passivated contact technology offers a solution to reducing diffusion and metal contact-induced recombination losses in bulk Si, so far it has primarily been confined to the rear of the cell because of high parasitic absorption losses in poly-Si [Yang et al. APL 2018] and inability to make good screen-printed contacts to very thin front poly-Si layers without compromising passivation quality and J₀ (Padhamnath et al. Solmat 2019).

Young et al. [1] attempted to fabricate selective area TOPCon contacts by reactive ion etching (RIE), but reported a loss of performance due to non-uniform etching and etching-induced loss of surface passivation. Attempts have also been made to fabricate selective area TOPCon using shadow masks for deposition of poly [2] and lithography-defined [3] patterns, but they are not industrially compatible.

In contrast, the instant method and system can be employed in a very simple low-cost way to passivate front and back surfaces of silicon wafers with opposite doping polarity (n and p). The approach, in some embodiments, involves only one high-temperature step with no masking step. The process can also include a simple and rapid method to pattern poly-Si using laser-induced selective oxidation, which can give much higher solar cell efficiency by increasing the voltage without losing current due to absorption in front side poly-Si.

The exemplary double-sided (DS) TOPCon cell device and method provide a unique opportunity to meet the cost and efficiency targets simultaneously. Compared to the lower cost full Al—BSF and PERC cells, which account for ˜95% of the market share today, the exemplary DS-TOPCon cells can achieve much higher efficiency (˜25%) because all the doped and metalized regions are displaced outside the Si absorber. Compared to the current ≥25% cells, the exemplary method of fabrication of DS-TOPCon cells is very straightforward with low capex that can employ inexpensive metallization and elimination of all the processing steps that are often used to remove, pattern, or etch deposited layers.

The exemplary method and device comprising low-cost DS-TOPCon cell can facilitate the development of low-cost Si/perovskite type tandem solar cells with an efficiency potential of ≥30%.

Poly-Si/SiOₓ carrier selective passivating contacts are an ideal candidate for next-generation solar cells because heavily doped regions, as well as metal contacts, are physically decoupled from the Si substrate via an ultra-thin tunnel oxide (≤15 Å), similar to the role of intrinsic a-Si layer in the >25% efficient HIT cells. However, poly-Si/SiOₓ contacts are much more thermally stable than a-Si-based HIT contacts and can withstand high firing temperatures (>700° C.) used for implementing the lowest-cost high throughput screen-printed contacts. When n+ poly-Si is deposited on top of tunnel oxide, it becomes electron selective contact (n-TOPCon) and vice versa for p-TOPCon. This is because heavily doped n+-poly-Si on top of tunnel oxide accumulates electrons and repels the minority carries holes at the tunnel oxide/n-Si interface due to appropriate n+−n band bending. These electrons are easily able to tunnel through the oxide from n-Si into the n+-poly while holes are blocked from entering the n+-poly, making it an electron selective contact and virtually eliminating hole recombination in the n+ region and metal contact. Similarly, p-TOPCon allows only the holes to tunnel through, making it a hole selective contact and reducing the electron recombination in the p+ region and metal contact. The interface recombination at the tunnel oxide-Si interface defects is also reduced due to the accumulation layer. Because of this dramatic reduction of minority carrier recombination in the heavily doped regions, metal contacts, and interface, extremely low J₀ values (<5 fA/cm²) and high cell efficiency can be achieved.

### Example #4

### Example Cell Structure, Modeling and Design to Attain Screen Printed ˜25% Efficiency Bifacial Full Area DS-TOPCon Cell

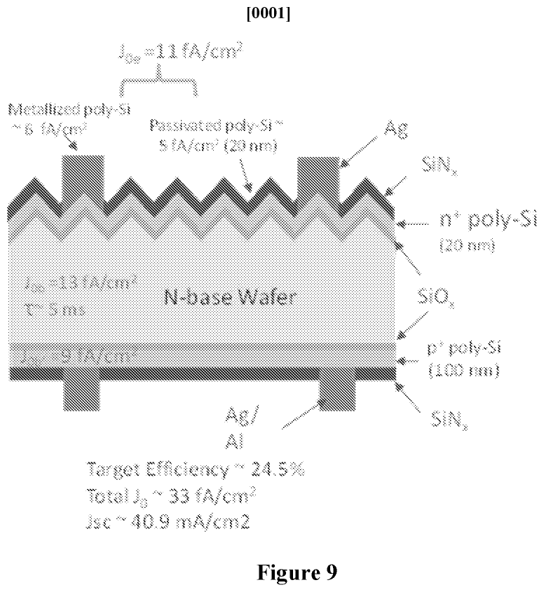

FIGS. 9-12 show a full area double side TOPCon cell structure with rear junction design on n-base Si can produce ˜25% efficiency at low-cost. FIG. 9 shows the exemplary cell structure with 100-200 nm full area p-TOPCon on the rear, and ˜20 nm textured full area n-TOPCon on the front with screen-printed contacts on both sides can produce ˜25% efficiency. Modeling below also supports and shows that this will require total recombination current J₀ of 33 fA/cm², with 13 fA/cm² coming from the front side n-TOPCon, 15 fA/cm² from bulk Si and 9 fA/cm² from the rear p-TOPCon. These are quite achievable using DS-TOPCon concept and n-base solar cell.

### Example #5

### Design and Development of Rear Junction Bifacial ˜25% Efficient Double Side Screen Printed Poly-Si/SiOₓ Passivated Contact Solar Cells

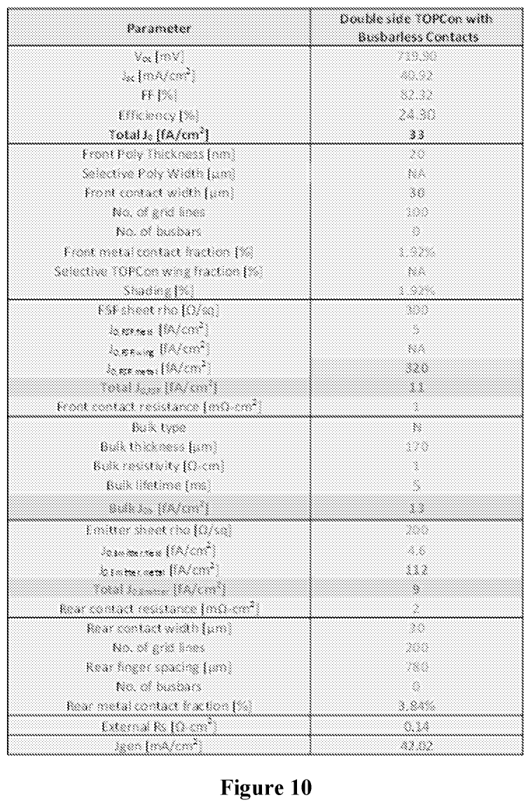

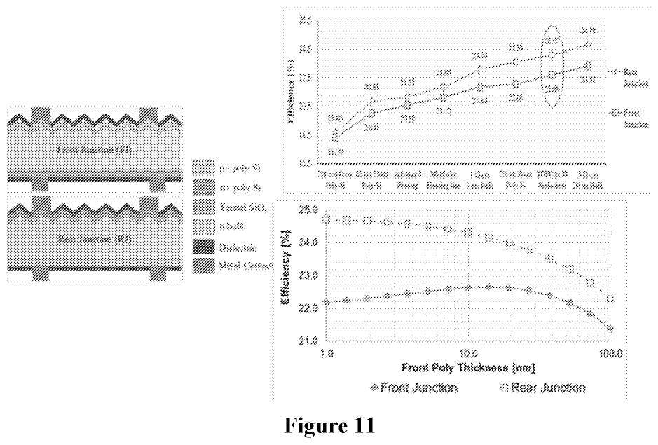

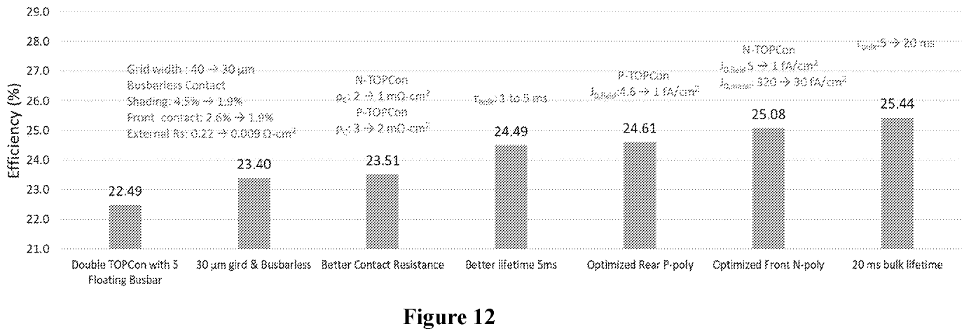

FIG. 10 shows detailed modeling with a list of all the practically achievable parameters to achieve ˜24% efficiency with this cell design. In fact, most parameters for each layer have been achieved in an experiment and are possible in mass production at a low cost. One design feature involves a rear junction cell with p-TOPCon on n-Si on the backside. FIG. 11. Rear junction DS-TOPCon device can give ˜25.0% efficiency with greater than 1% efficiency enhancement over front junction DS-TOPCon cell. FIG. 12 gives a step-by-step technology roadmap to achieve ≥25% efficiency for this cell design by quantifying the benefit of each technology enhancement and innovation.

FIG. 11 shows an advantage of the exemplary rear junction cell over the traditional front junction cell. The front junction design may prevent the use of thin poly-Si to avoid significant absorption loss in the front poly-Si layer. However, in a rear junction device, efficiency becomes insensitive to the thickness and sheet resistance of front n-poly Si, without any penalty in carrier transport and collection of electrons on the front of the device. FIG. 3 also shows that a rear junction device can produce >1% higher efficiency than a front junction device.

Thus, the modeling and subsequent analysis reveal that to get to 25% efficiency for the cell design, the exemplary method may 1) provide defect-free n+ and p+ doped poly-Si/SiOₓ contact layers with metalized recombination current density (J₀) of ≤10 fA/cm²; 2) reduce bulk defects and optimize lifetime (>3 ms) and resistivity to achieve J₀ bulk of ≤10 fA/cm²; 3) significantly reduce parasitic absorption by depositing very thin poly-Si (˜20 nm thickness) on the front layer; 4) develop advanced screen-printing paste and firing conditions to make ohmic contacts to −20 nm poly-Si without compromising J₀ and fill-factor (FF>82.5%). It is possible to make screen-printed contacts to −35 nm TOPCon; and 5) implement a back junction cell design that desensitizes the cell performance with respect to the front poly sheet resistance, enabling the use of very thin poly-Si on the front. The modeling demonstrates that fabrication of low-cost DS-TOPCon back junction (n+−n−p+) cell with the above design and parameters can produce low-cost, fully screen-printed bifacial cells with Voc ˜720 mV, Jsc ˜41.5 mA/cm², FF ˜0.825 and η˜25%.

### Example #6

### An Initial Attempt and Demonstration of the Concept of Screen Printed Asymmetric TOPCon Cell (Thin Front n-TOPCon and Thick Rear p-TOPCon by Traditional Ex Situ Doping with Multiple Masking and High-Temperature Steps)

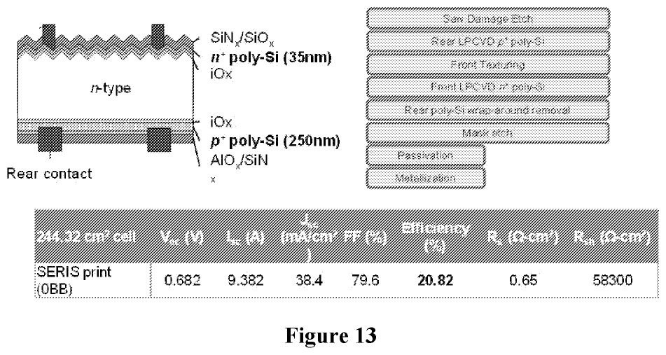

The exemplary device has achieved very low 1-2 fA/cm² J₀ on un-metalized textured n-TOPCon coated with Al₂O₃/SiN dielectric on the front and 5 fA/cm² J₀ for screen-printed n-TOPCon with 5% metal coverage. Similarly, on the rear side, the exemplary device has so far achieved 5 fA/cm² for unmetallized planar p-TOPCon and ˜15 fA/cm² for a metalized p-TOPCon on the back with ˜10% metal coverage. These are close to what is needed in a final device. The exemplary method can be employed to make reasonably good screen-printed contact to 35 nm n-poly-Si on the front by choosing the right paste and firing condition. Based on current results, it is believed that this can be improved further, and it is possible to successfully implement screen printed 20 nm poly-Si contact on the front. A study recently made the first prototype to make such a device to test its viability. The method grew ˜15 A tunnel oxide by chemical oxidation of Si in heated HNO₃ solution and deposited doped poly-Si layers by LPCVD followed 850° C./30 min anneal in inert ambient to activate dopants for making n and p-TOPCon. The method has also produced n and p-TOPCon by growing intrinsic poly first and then doing ex-situ doping of front with P diffusion and back using B diffusion. Front n-TOPCon was coated with Al₂O₃/SiNx stack, and rear TOPCon was coated with SiNx prior to screenprint metallization. Front and back contacts were screen printed and fired simultaneously. FIG. 13 shows the cell structure and process flow, and cell performance with 35 nm n-TOPCon. Further optimization of contacts, bulk lifetime, and TOPCon can get to ˜25% efficiency.

FIG. 13 is a schematic of DS-TOPCon cell (left), and process flow for cell fabrication (right).

### Example #7

### Novel and Simple Method to Fabricate High Quality Double Side TOPC by Ex Situ Doping of B and P in a Single High Temperature Step Prior to Selectively Thinning the Front Side

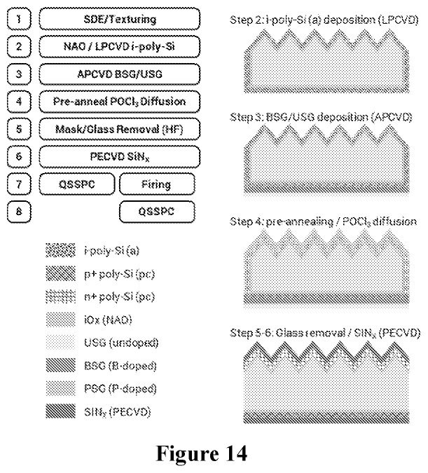

Besides the exemplary cell design, modelling, and efficiency potential of this cell structure, a method is disclosed to produce low-cost DS-TOPCon precursor. This involves growing ˜200 nm undoped intrinsic i-poly-Si on top of a tunnel oxide on both sides of the wafer by LPCVD (low-pressure chemical vapor deposition) at ˜580° C. In an experiment, ˜15 Å thick tunnel oxide is grown by chemical oxidation of Si in HNO₃ at ˜100° C. prior to LPCVD of intrinsic poly on both sides. Next, the exemplary method deposited APCVD grown borosilicate glass (BSG) only on the backside and then capped it with APCVD grown thick undoped SiOₓ (USG) (FIG. 14). FIG. 14 shows a process flow of DS-TOPCon precursor (left) and cross-sectional schematic diagrams of DS-TOPCon precursor in process (right)

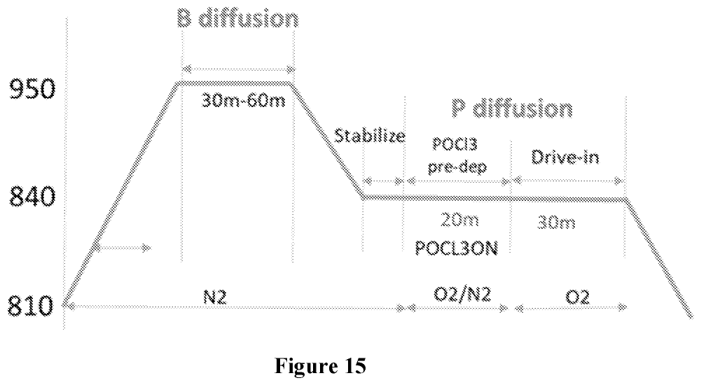

FIG. 15. Development of receipt for ex-situ Doped N- and P-TopCon using APCVD B glass and POCL₃ diffusion. FIG. 16 shows the measured iV_{oc} and iFf of finished DS-TOPCon precursor with there different pre-annealing temperatures.

This sample is then heat-treated for 30 min in a POCl₃ ambient in a tube furnace to form n-TOPCon on the front at 850° C. by diffusing P into the intrinsic front poly-Si. Note that Phosphorus diffusion on the back is blocked by thick undoped APCVD SiOₓ on the rear side. The study found that 850° C. was not sufficient to drive enough B from APCVD BSG on the backside, which requires ˜950° C./30 min heat treatment to achieve desired sheet resistance of 150 ohms/. This led to the development of a heat treatment profile shown in FIG. 7 involving ˜950° C./1 hour heat treatment in N2 first to drive sufficient B on the backside followed by lowering the temp to 840° C. followed by POCL₃ diffusion for 30 min to form n-TOPCon during the same thermal cycle. Thus, in a single high temperature step, both n and p TOPCons are formed without any auto doping or cross-diffusion due to the presence of thick oxide on the back. Thick oxide not only blocks P diffusion on the backside but also prevents B out diffusion onto the front side. Thus, there are no masking steps required, which makes the process very simple, elegant, and inexpensive. FIG. 16 shows that a DS-TOPCon precursor formed by this unique process resulted in excellent implied Voc of 725 mV with implied FF of ˜86%, appropriate for 25% cell.

### Example #8

### A Selective Chemical Etching Method of Converting DS-TOPCon with Symmetric Thickness to Asymmetric DS-TOPCon with 200 nm p Poly on Back and ˜20 nm n-Poly on Front

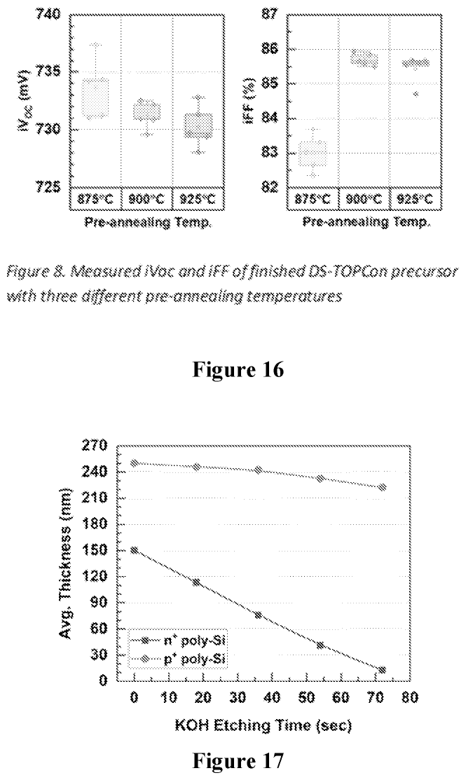

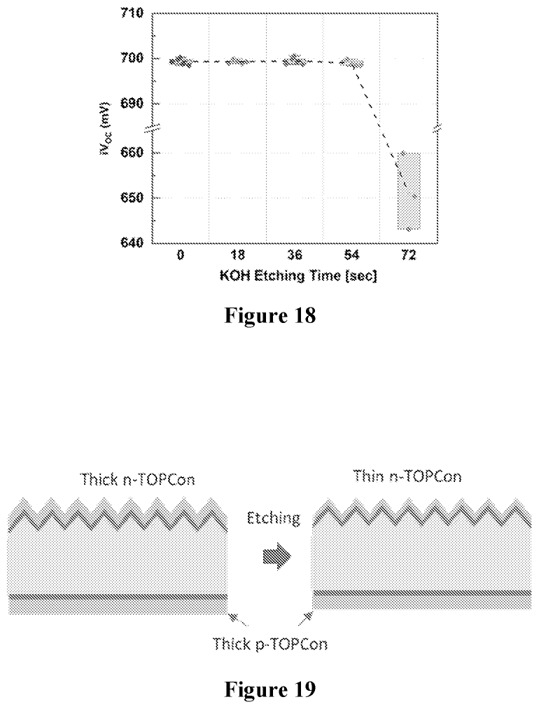

Once the method has provided a thick ˜200 nm n-TOPCon on the front and a 200 nm p-TOPCon on the rear, the exemplary method may include a selective etch process, which in less than 2 min can convert the above symmetric DS-TOPCon to asymmetric n-TOPCon with ˜200 nm p-TOPCon on the back and only ˜20 nm textured n-poly on the front. This is a very dilute KOH solution (20% at 40° C. for <2 min). This solution n-poly about 5-10 times faster than p-poly-Si as experimentally demonstrated in FIG. 17 without degrading the quality of J₀ and iVoc of the DS-TOPCon structure (FIG. 18). FIG. 17 Comparison of etching rate between n-poly-Si and p-poly-Si. FIG. 18 Comparison of etching rate between n-poly-Si and p-poly-Si. FIG. 19. Schematic images from Symmetric DS-TOPCon to asymmetric n-TOPCon with ˜200 nm p-TOPCon on back and only ˜20 nm textured n-poly on front after selective etching. This is the structure can potentially achieve 25% Si solar cells based on the exemplary modeling.

Thus, not only has the design of a manufacturable DS-TOPCon cell been demonstrated to achieve 25% efficiency, but it is also revealed that the exemplary method can be used to produce such structure by ex-situ doping of intrinsic thick symmetric poly followed by <2 min chemical etching in a specific KOH solution.

Several groups have reported efficiencies exceeding 25% on laboratory-scale TOPCon cells employing single side poly-Si based passivated contacts (Fraunhofer ISE and ISFH). Two cell manufacturers, Trina Solar and Jolywood, have started pilot production of single side n-TOPCon cells with an efficiency of ˜22.5%. Some prominent examples of high-efficiency R&D cells with passivated contacts in the literature include 26.7% Si heterojunction IBC cells by Kaneka (Yoshikawa et al. Nature Energy 2017), 25.2% tunnel layer passivated IBC cells by SunPower (Smith et al. IEEE PVSC 2016), 26.1% poly-Si on oxide (POLO) IBC cell by ISFH (Haase et al. Solmat 2018), and 25.7% single side rear n-TOPCon cell by Fraunhofer ISE (Richter et al. Solmat 2017) with conventional B diffusion on the front, evaporated and photolithography contacts. The ˜26% TOPCon cells were realized on a small area (<16 cm²) with non-manufacturable technologies, but they provide the existence proof of the potential of this concept for achieving very high efficiency even with a single side TOPCon.

Even though Poly-Si based passivated contact technology offers a solution to reducing diffusion- and metal contact-induced recombination losses in bulk Si, so far it has primarily been confined to the rear of the cell because of high parasitic absorption losses in poly-Si [Yang et al. APL 2018] and inability to make good screen-printed contacts to very thin front poly-Si layers without compromising passivation quality and J₀ (Padhamnath et al Solmat 2019). Therefore, an industry-feasible approach is disclosed herein to deploy low-cost, manufacturable screen printed TOPCon on both sides to exploit the full potential of this technology and concept. This will not only enhance the efficiency but also reduce the cell processing cost by eliminating traditional diffusion technology. It is shown that the modeling, design, and a fabrication sequence can achieve commercial ready fully screen printed ˜25% bifacial DS-TOPCon cells by incorporating thin electron selective n+-poly-Si/SiOₓ passivated contact on the textured front and 200 nm thick hole selective p+-poly-Si/SiOₓ passivated contact on the planar rear surface. In addition to the cell architecture and its efficiency potential, it is shown that the low-cost method of making a thick DS-TOPCon in a single high temperature step can be performed with no additional masking steps to achieve ˜250 nm planar thick b-TOPCon on the back and textured thick ˜200 nm n-TOPCon on the front. This involved ex situ doping of intrinsic poly silicon on both sides using APCVD B on the back and POCL diffusion on the front side without any cross doping and contamination. Finally, the exemplary method can be employed in manufacturing operations to convert the above thick (˜200 nm) double side TOPCon to an asymmetric DS-TOPCon in less than 2 min by a novel selective chemical etch which attacks n-TOPCon faster (˜5 times) than p-TOPCon, resulting in the desirable ˜200 nm planar p-TOPCon on the back and ˜20 nm textured n-TOPCon on front. This is exactly what is needed to achieve ˜25% DS-TOPCon cells if good quality screen-printed contacts can be made on both sides. Screen printed contacts and can achieved efficiency of ˜21% and even ˜25%, as predicted by the computer modeling described herein. To the best of the inventor's knowledge, this has never been done before.

In addition, the exemplary cell structure will be bifacial with a much lower temperature coefficient that will further increase energy harvesting and lower LCOE. Finally, most PERC manufacturing lines today can be easily transformed into TOPCon lines by addition of poly-Si deposition tools, enabling the rapid and low-cost adaptation/transfer of this technology. In addition to the exemplary concept, cell design, and efficiency potential, it is demonstrated an apparatus that can achieve ˜21% large area screen printed double side TOPCon cell with screen-printed contact on ˜35 nm poly on front. Based on modeling and results, it is possible to reduce this front poly thickness to ˜20 nm and optimize other material parameters to get to; ≥25% efficiency.

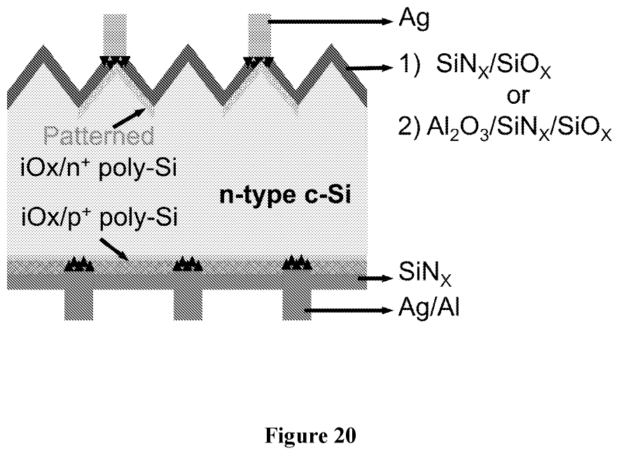

Accordingly, provided is a quantitative understanding and requirements of making high efficiency screen-printed RJ selective DS-TOPCon solar cells (FIG. 20). This cell structure is composed of full-area iOx/p+ poly-Si (p-TOPCon) on the back, but selective-area iOx/n+ poly-Si (n-TOPCon) on the front side to minimize the parasitic light absorption losses in poly-Si layer.

Focusing on the requirement and challenges in passivating the front field region of selective DS-TOPCon cell to achieve high cell efficiency, two different passivation schemes, Al₂O₃/SiNX:H and SiNX:H, were investigated to minimize the recombination current density (J₀) in the field region. Various symmetric test structures were fabricated to assess the J₀ values of the passivated field regions. In addition, we fabricated the selective DS-TOPCon cell using two different front surface passivation schemes.

After saw damage etching (SDE) in 20% wt potassium hydroxide (KOH) solution at 80° C. for 9 minutes, both sides of the wafers were textured using the standard texturing process. A stack of ultra-thin interfacial oxide (iOx) and intrinsic poly-Si of desired thickness were deposited on both planar and textured samples in a single step two-stage process in low pressure chemical vapor deposition (LPCVD) system. The ex-situ doping of the poly-Si layers was performed in an atmospheric tube diffusion furnace), using liquid phosphorus oxychloride (POCl₃) and boron-tribromide (BBr3) as dopant sources, resulting in symmetric n-type and p-type poly-Si structures, respectively. Up to this process stage, a batch of symmetric textured n-TOPCon (90 nm) and planar p-TOPCon (250 nm) samples were fabricated and ready for the next process.

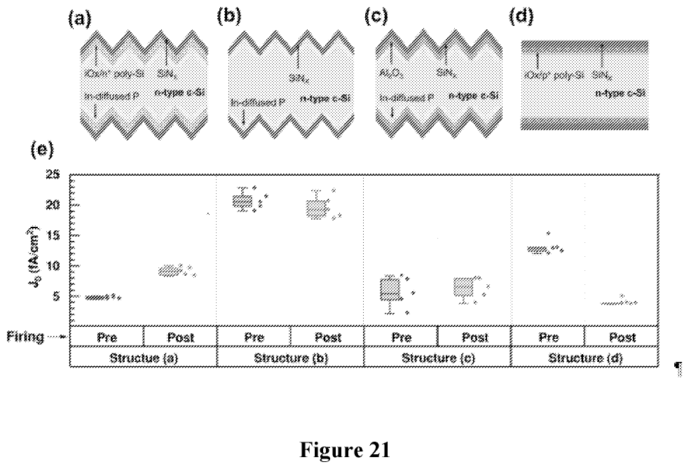

A proportion of these symmetric textured n-TOPCon samples were dipped in 9% wt KOH solution at 40° C. to etch off the n+ poly-Si. This etching process removed the entire n+ poly-Si, but was stopped its reaction exactly at iOx interface, which was demonstrated in our previous work [4]. Due to the etch protection by iOx, a weakly phosphorus (P) in-diffused layer under the iOx, formed during the ex-situ doping process, was preserved, which imitates the field region of selective DS-TOPCon cell (FIG. 20). Then, for the fabrication of structure (c) in FIG. 21, a 30 Å of Al₂O₃ film was deposited using plasma-enhanced atomic layer deposition (ALD) system. Finally, both sides of all the samples were passivated with SiNX:H using plasma-enhanced chemical vapor deposition (PECVD) system. High temperature firing process was performed in an industrial belt furnace.

The recombination current density (J₀) of all test structures was measured at an injection level of 5×10¹⁵ cm⁻³ using a contactless photoconductance decay measurement tool (WCT-120) [5]. The current-voltage (J-V) characteristics of the fabricated selective DS-TOPCon solar cells were measured using a flash tester (FCT-450).

Impact of front J₀, field on efficiency of selective DS-TOPCon cell

To start with, a 2D device simulation was performed for selective DS-TOPCon cell structure using Quokka 2 [6] with practically achievable device parameters to find out the target J₀ value for the front field region, which can attain ˜25.0% cell efficiency. As shown in Figure, the front J₀, field should not exceed 5 fA/cm² to cross the 25.0% cell efficiency with selective DS-TOPCon cell structure. Also, it shows that the cell efficiency of rear junction device is extremely sensitive to the front field passivation, projecting nearly 1.3% absolute efficiency degradation as the J₀, field rises from 5 to 30 fA/cm².

### Investigation of Passivation Property of Each Region of Selective DS-TOPCon Solar Cells

To evaluate the feasibility of the proposed selective DS-TOPCon cell structure (FIG. 20) and identify the potential performance-limiting factors, the passivation property of each region of the cell was individually monitored. As summarized in FIG. 21, the J₀ of each test samples were measured before and after high temperature screen-printed contact firing step (˜740° C.). The symmetric textured n-TOPCon (structure (a)) and planar p-TOPCon (structure (d)) samples showed excellent passivation quality after simulated firing, resulting in full-area passivated J₀ values of ˜9 fA/cm² and ˜4 fA/cm² respectively.

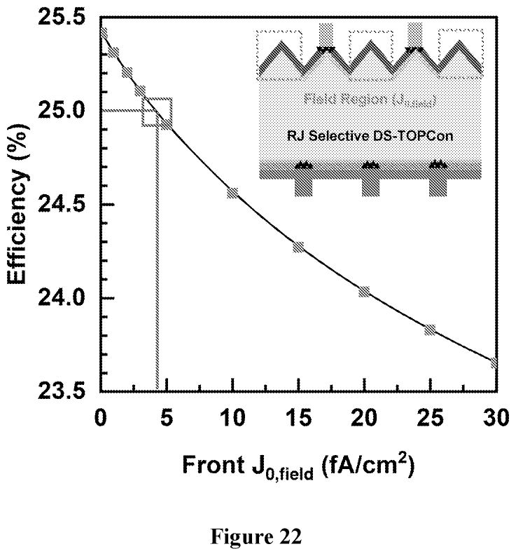

Since, in a real device, textured n-TOPCon is replaced by dielectric passivated textured n-type c-Si, therefore, we also studied dielectric passivated fields region on the front. We investigated and compared the passivation quality of SiNX:H layer and Al₂O₃/SiNX:H stack. FIG. 21 shows that Al₂O₃/SiNX:H stack passivated the surface extremely well, resulting in textured field J₀ value as low as 4 fA/cm², which is comparable to n-TOPCon and is consistent with the requirement for 25.0% cell efficiency (FIG. 22). This excellent passivation is attributed to the large negative fixed charge density (˜1×10¹³/cm²) in Al₂O₃ layer which provides excellent passivation via formation of inversion layer at interface of AlO₃/n-Si. On the other hand, SiNX:H passivation resulted in a relatively high J₀ of 18-22 fA/cm². This may be due to the poor chemical passivation at the SiNX:H/n-Si interface and the positive fixed charge density in SiNX:H is not enough to create strong accumulation layer to lower the J₀ to the desired value of <5 fA/cm².

### J-V Characteristic of Fabricated Selective DS-TOPCon Cell

After monitoring the recombination behaviors of each layer (J₀ assessment), we made an attempt to fabricate the selective DS-TOPCon cell. Error! Reference source not found. TABLE 1, below, summarizes J-V characteristics of fabricated selective DS-TOPCon solar cell with above two different front field surface passivation schemes. Contrary to our expectation, we found that the performance of the cell passivated with SiNX layer was superior to the cell passivated with Al₂O₃/SiNX stack. Further C-V analysis revealed that Al₂O₃ layer provided superior surface passivation quality because it has larger negative fixed charge density (˜1×1013/cm²) than the positive charge density (1×10¹²/cm²) in the SiNX:H. However, the cell performance of Al₂O₃/SiNX:H stack passivated cell was relatively inferior because the depletion and inversion layers underneath the dielectric layer attracts minority carriers to the surface, which aggravated the carrier collection. In addition, the positively charged p+ inversion layer in the field and the n+ region underneath the metal contacts form a tunnel junction to trigger tunneling or leakage of minority carriers. This causes a substantial drop in the cell VOC and FF, as seen in TABLE 1Error! Reference source not found. Thus, neither SiNX:H nor Al₂O₃/SiNX:H passivation schemes are sufficient for very high efficiency solar cells. Recently we have conducted the experiment with 15 nm thermal SiO₂ capped with SiNX:H on the field region. A preliminary optimization on this passivation scheme has given J₀ values of ˜10 fA/cm², which getting close to the target J₀, field value. Further dielectric optimization and cell fabrication is in progress and will be reported at the conference.

TABLE 1

| Passivation | VOC | JSC | FF | η | pFF | J₀₂ |
|---|---|---|---|---|---|---|
| stack | [mV] | [mA/cm²] | [%] | [%] | [%] | [nA/cm2] |
| SiNX | 687 | 38.7 | 79.3 | 21.1 | 82.2 | 8 |
| passivation | | | | | | |
| Al₂O₃/SiNX | 675 | 37.5 | 78.5 | 19.8 | 80.6 | 18 |
| passivation | | | | | | |

### Summary of J-V Parameters of Fabricated Selective DS-TOPCon Solar Cells

Thus, the performance of selective DS-TOPCon cell structure is largely dependent on the front surface passivation since vast majority of carriers are photo-generated near the top surface and the collecting junction is located at the back. A 2D device simulation showed that in order to cross the 25.0% cell, the passivated J₀, field should be below 5 fA/cm². From the symmetric test sample, it can be seen that Al₂O₃/SiNX:H passivation stack can achieve the J₀ value as low as 4 fA/cm², which satisfies the high efficiency requirement from the basis of J₀ value. To demonstrate and verify the feasibility of Al₂O₃/SiNX:H passivation stack, a selective DS-TOPCon cells were fabricated and passivated its front surface with Al₂O₃/SiNX:H stack. However, due to the existence of P in-diffusion on the front field region, this passivation stack formed strong inversion layer in the field region, which detrimentally affected the J-V parameters of the finished cells. Both Al₂O₃/SiNX:H and SiNX:H passivation schemes investigated in this work were not sufficiently satisfy the requirement for high efficiency solar cell. Finding out the passivation scheme which can achieve J₀, field <5 fA/cm2 and at the same time induce the strong accumulation layer on the field region will be a key to cross the 25.0% cell efficiency with selective DS-TOPCon cell structure.

Utilizing a poly-Si/SiO₂ contact on the front as well as the rear of the solar cell can further improve the passivation and mitigate metal-induced recombination on both sides. Patterning the front poly-Si such that it is present only under the metal grid can help minimize parasitic absorption while reaping the benefits of a front passivated contact under the metal grid [7]. While there are several traditional methods of patterning the poly-Si ([8], [9]), laser-oxidation is a unique, fast, and simple process to achieve this [4]. In addition, it can pattern quite narrow lines. This method forms an ultra-thin SiOₓ mask on the laser-processed regions that allows etching the poly-Si selectively between the metal fingers using KOH, thereby achieving the desired patterned structure on the front side of the solar cell as shown in FIG. 1. The patterned poly-Si lines will hereafter be referred to as “poly-fingers”.

Tunnel-oxide passivated contact (TOPCon) solar cells are quickly replacing conventional PERC-like structures in commercial production [10]. These contacts utilize a doped poly-Si/SiO₂ stack to physically isolate the metal contacts from the absorber while providing the appropriate band bending to enhance charge carrier collection. This enables solar cells utilizing a TOPCon stack to achieve significantly higher open circuit voltages (Voc) [11]. However, due to the high absorptance of poly-Si, the application of the TOPCon stack is restricted to the rear of the solar cells while utilizing a conventional diffused layer on the front.

The ability to form narrow poly-Si fingers using a laser-oxidation process. Is described herein. Microscopic evidence that the laser-grown oxide can protect the underlying polysilicon from KOH etching is presented herein. The impact of the laser-oxidation process on the electrical performance of the device is assessed through electrochemical capacitance-voltage (ECV) doping profile measurements. In addition, we fabricated aluminum rear junction PhosTop solar cells with a full-area thick n+ poly-Si layer on the front surface, with and without laser irradiation (FIG. 24).

### Fabrication and Characterisation of Patterned Poly-Si Structures

Both cell structures and microscopy samples were fabricated on random pyramid textured ˜1 Ωcm n-type Cz-Si wafers. The wafers were then RCA cleaned and immersed in HNO₃ at 100° C. for 15 min, growing about 15 Å of SiO2. Next, ˜200 nm in-situ phosphorus-doped poly-Si was grown using LPCVD in a Tystar system at 588° C., followed by a crystallization and dopant activation anneal at 875° C. for 30 min in a Centrotherm tube furnace.

For the microscopy samples, after the poly-Si was grown, 150 μm wide poly-fingers were processed on the front side of the wafer using a Coherent Avia UV (355 nm) nanosecond-pulsed laser at a power of 4 W (measured before the focusing optics) and a scan speed of 400 mm/s. Following this, the wafers were immersed in 9% wt KOH at 40° C. for two minutes. This was found to be enough to etch the 200 nm thick poly-Si in the field region between the patterned laser lines, probably without damaging the tunnel oxide. These patterned samples were then observed in a Thermo Helios 5 CX SEM

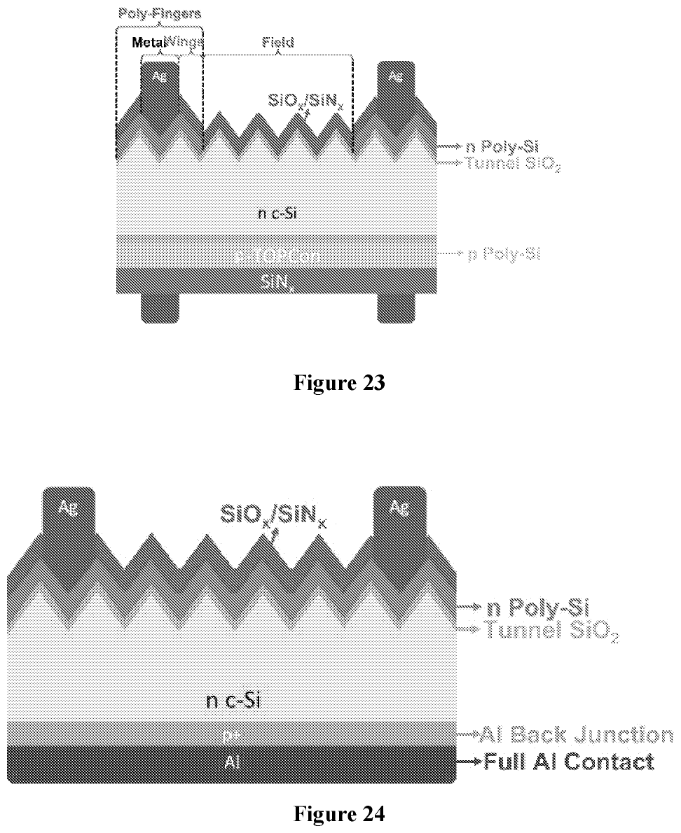

To assess laser damage without introducing complexities of metal alignment, the cell structures were fabricated (FIG. 23) with the entire front surface of the wafer laser exposed using the process described earlier. Then, the front surface was masked with PECVD SiNx and immersed in 20% wt KOH at 65° C. for 10 min to remove the poly-Si wrap-around and planarize the rear surface of the wafer. Following that, the wafers were RCA cleaned, the SiNx mask was removed in 10% wt HF, and a double layer antireflection coating with 45 nm SiNx capped with 90 nm SiOₓ was grown through PECVD. For metallization, the cell was screen-printed with an H pattern (100 fingers, 35 μm) using Ag pastes on the front and full area Al on the back. Finally, the samples were fired in a belt furnace at a peak temperature of 760° C. The completed cells were measured on a Sinton FCT-450 flash tester.

### Effects of Poly-Finger Geometry on Cell Performance

For brevity, the regions of the poly-fingers not covered by metal are referred to as the ‘wing area.’ The exposed poly-Si in the wing area incurs parasitic light absorption. FIG. 25 shows Quokka 2 device simulations were performed to quantify the impact of poly-finger thickness and width on solar cell performance, using experimental details of samples and an optical model developed earlier [4]. The results of these simulations are summarized in FIG. 25. Note that the wing area fraction is calculated after subtracting the width of the metal lines (30 μm) from the width of the poly-finger, and then calculating the ratio of the exposed poly-Si area for 100 lines on a 156 mm wafer.

It was found that thicker and narrower poly-fingers are detrimental to solar cell performance. While thicker poly-Si fingers cause increased parasitic absorption, they are beneficial for minimizing loss in VOC with fire-through metallization. On the other hand, having wider poly-fingers increases parasitic absorption while increasing its contribution to the J₀. Additionally, we find that for narrower poly-Si fingers, the efficiency is less sensitive to poly-Si thickness, allowing the use of thicker poly-Si for lower metal-induced damage. This suggests that narrow, thick poly-Si fingers could help improve the performance of the double-side passivated contact solar cells. Poly-Si patterning with laser oxidation is ideally suited for that.

### Micrography Analysis of Laser Patterning

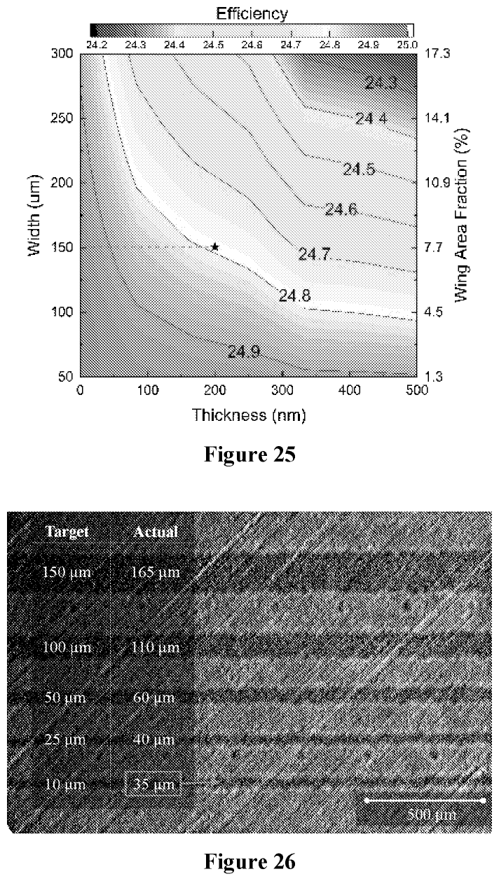

FIG. 26 shows that our laser can be used to pattern poly-Si fingers as narrow as 35 μm. The measured width obtained after patterning was found to exceed the target width of the pattern by approximately 10-15 μm. This is likely due to the output of the laser spot being a gaussian beam. Additionally, due to the spot-size limitations of our laser, the narrowest line that can be patterned is about 35 μm wide. This is close to the state of the art for the width of screen-printed grid metallization [10]. However, patterning of poly-Si by screen print resist will require several additional steps.

Protection of Poly-Si from KOH Etch Due to Laser-Oxide

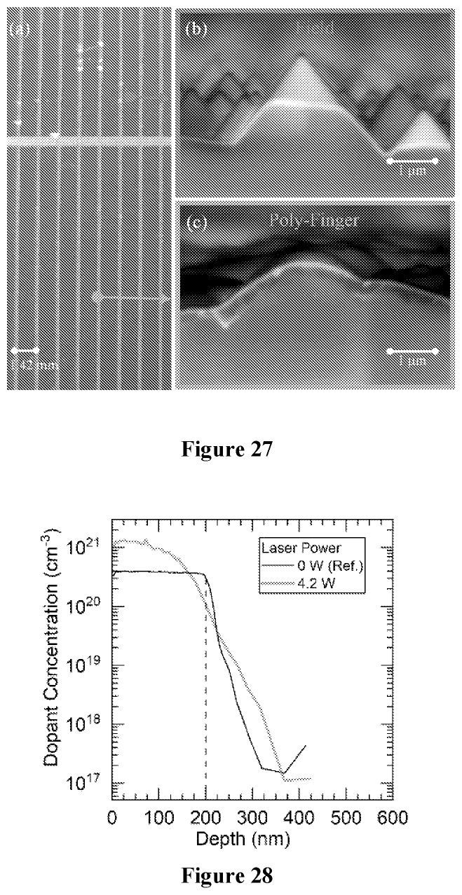

FIG. 27(a) is a plan view photograph of a laser patterned sample capped with silicon nitride showing multiple poly-fingers and a busbar. FIG. 27(b) is a cross-section image of a single texturing pyramid in the field region. FIG. 27(c) is rounded pyramid in the poly-finger region showing presence of Poly-Si after KOH etching. In the proposed device structure, after the laser patterning on the front, the poly-Si in the field region is etched in KOH (40° C., 9% wt). Subsequently, the anti-reflection dielectric is deposited rendering the wafer ready for metallization. FIG. 27(b) shows that 2 min of etching in KOH is sufficient to remove the poly-Si without affecting the textured morphology of the wafer in the field region. Further, in FIG. 27(c), it can be seen that in the patterned poly-finger region, poly-Si is indeed present under the anti-reflection coating. However, we observe that the texturing in the laser-oxidized region is rounded, causing the poly-Si to redistribute, thereby resulting in non-uniform thickness. The rounding of the pyramids and resultant laser damage is consistent with prior observations [4].

### Effect of Laser Processing on Poly-Si Doping

Due to the morphological changes seen after laser processing, we investigated the change in the doping profile in the poly-Si and Si before and after laser irradiation. Electrochemical capacitance-voltage (ECV) measurements show the concentration of electrically active dopants in the sample as a function of depth from the surface. In FIG. 28 it can be seen that for the reference sample (no laser irradiation), the concentration of active phosphorus is constant until nearly 200 nm after which it falls rapidly. This shows that the activation of phosphorus in the poly-Si is uniform with depth (˜4×10²⁰ cm⁻³) and that there is a minimal in-diffusion into the Si wafer through the tunnel oxide. For the sample irradiated with the UV laser, the surface concentration increased to 10²¹ cm⁻³. This suggests the activation of inactive dopants that were trapped in regions of low crystallinity. This is consistent with the decrease in sheet resistance of the layer due to laser irradiation observed in previous work [4]. Furthermore, after laser irradiation, the phosphorus concentration begins to decrease earlier and the change in concentration is more gradual. We hypothesize that this could be due to disruption or damage to the tunnel oxide layer causing the dopants to drive into the c-Si substrate.

### Simplified Solar Cells

The morphological and electrical changes in the poly-Si layer could impact solar cell performance. Laser irradiation may cause a substantial deterioration in Jo, which may be partially recovered after PECVD SiNx deposition.

To further understand the impact of the laser patterning process on solar cell performance, a full area laser irradiated solar cell (No patterning or KOH etching) with a full area Al contact on the rear side was fabricated to compare with an otherwise identical non-laser processed solar cell (reference). Table II shows the lighted IV data under AM1.5 g illumination.

TABLE II
LIV data of the fabricated cells.

| | Voc (V) | Jsc (mA/cm2) | FF (%) | Efficiency (%) |
|---|---|---|---|---|
| No Laser | 650.43 | 33.11 | 77.99 | 16.80 |
| 4 W Laser | 634.15 | 29.86 | 78.23 | 14.81 |

Both solar cells have very low short-circuit current densities. This is expected due to the significant parasitic absorption loss in the ˜200 nm of full-area poly-Si on the front side. Additionally, the laser-irradiated solar cell has an even lower JSC due to increased reflection and worse light trapping arising from the rounded pyramids. Furthermore, the open circuit voltage of the lasered cell is ˜16 mV lower than the reference cell. This is likely due to the deterioration of passivation arising from laser damage. For the proposed device (FIG. 23), the area fraction of the laser-damaged region will be significantly lower (<5%) than it is in this device. As a result, the detrimental effect of the laser on VOC would also be commensurately lower. Importantly, the fill factors for the two cells are comparable. This shows that the laser damage does not deteriorate metallization or contact formation. Cell fabrication with selective poly-Si fingers on the front is in progress and the cell results and analysis will be presented at the conference.

Narrow poly-fingers may be pattern with an objective of minimizing parasitic absorption and the effects of laser damage on the passivation of the cell. To this end, it is shown that using laser oxidation, lines as narrow as 35 μm can be patterned. Further, more precise laser systems can pattern significantly narrower lines allowing for minimal wing area exposed to light. Therefore, in practice, the line width of the poly-finger would be limited by the width of the metal fingers and the precision of alignment for metallization. It is also shown that while the laser-oxide can protect poly-Si from etching, it is at the expense of significant morphological and electrical changes, which reflects as a deterioration of passivation in the completed solar cell. While ECV results suggest damage to the SiO₂ layer in the TOPCon stack, this can be verified using TEM imaging. Despite this, due to the very small overall area fraction of the lasered region in the proposed selective area front contact, the effect of this damage could be minimized. Additionally, for narrower poly-fingers, it is possible to use thicker poly-Si to mitigate damage without incurring significant parasitic absorption losses. These results advocate for the use of laser-oxidation for patterning poly-Si contacts, a fast, scalable, and tunable alternative to traditional patterning techniques.

In another aspect, a DS-TOPCon cell design is disclosed with selective poly-Si contacts on the front, only below metal contacts. The TOPCon area coverage on the front is only ˜5% to prevent absorption in poly-Si. The remaining 95% area is a bare Si wafer coated with Al₂O₃/SiN coating, which provides excellent passivation. This resulted in J₀ or Voc comparable to full area DS-TOPCon but with no appreciable absorption in front poly-Si. It also allows the use of thick poly-Si on front without risking the J₀ degradation due to screen-printed contacts. Modelling shows this cell structure can produce 25% cells at a low-cost.

In another aspect, an experimental formation is also disclosed of a low-cost DS-TOPCon precursor using only one high-temperature step without masking steps. In this process, Boron (B) is diffused in the back intrinsic poly using BSG glass, and Phosphorus (P) is diffused on the front intrinsic poly by POCL₃ diffusion during the same high-temperature cycle without any cross doping. It is demonstrated that this unique, low-cost process gives excellent J₀ and iv_{oc} values consistent with 25% efficiency.

Another aspect of the disclosure involves patterning of front poly by selective UV laser oxidation, followed by KOH etching of poly. A 1-4 nm laser-grown oxide was found to be sufficient for masking KOH etching, resulting in well-defined polyfingers. Screen-printed contacts are formed on top of these poly fingers by firing through a SiN coating. It is shown herein that SiN deposition restores the laser-induced degradation of J₀. This unique process was successfully demonstrated.

The exemplary system and method may be employed for silicon cell manufacturing. Solar cell manufacturers can employ equipment such as LPCVD or PECVD to their TOPCon production lines for such silicon cell fabrication.

Some references, which may include various patents, patent applications, and publications, are cited in a reference list and discussed in the disclosure provided herein. The citation and/or discussion of such references is provided merely to clarify the description of the present disclosure and is not an admission that any such reference is “prior art” to any aspects of the present disclosure described herein. In terms of notation, “[n]” corresponds to the nth reference in the list. All references cited and discussed in this specification are incorporated herein by reference in their entireties and to the same extent as if each reference was individually incorporated by reference.

Although example embodiments of the present disclosure are explained in some instances in detail herein, it is to be understood that other embodiments are contemplated. Accordingly, it is not intended that the present disclosure be limited in its scope to the details of construction and arrangement of components set forth in the following description or illustrated in the drawings. The present disclosure is capable of other embodiments and of being practiced or carried out in various ways.

It must also be noted that, as used in the specification and the appended claims, the singular forms “a,” “an,” and “the” include plural referents unless the context clearly dictates otherwise. Ranges may be expressed herein as from “about” or “5 approximately” one particular value and/or to “about” or “approximately” another particular value. When such a range is expressed, other exemplary embodiments include the one particular value and/or to the other particular value.

By “comprising” or “containing” or “including” is meant that at least the name compound, element, particle, or method step is present in the composition or article or method, but does not exclude the presence of other compounds, materials, particles, method steps, even if the other such compounds, material, particles, method steps have the same function as what is named.

In describing example embodiments, terminology will be resorted to for the sake of clarity. It is intended that each term contemplates its broadest meaning as understood by those skilled in the art and includes all technical equivalents that operate in a similar manner to accomplish a similar purpose. It is also to be understood that the mention of one or more steps of a method does not preclude the presence of additional method steps or intervening method steps between those steps expressly identified. Steps of a method may be performed in a different order than those described herein without departing from the scope of the present disclosure. Similarly, it is also to be understood that the mention of one or more components in a device or system does not preclude the presence of additional components or intervening components between those components expressly identified.

The term “about,” as used herein, means approximately, in the region of, roughly, or around. When the term “about” is used in conjunction with a numerical range, it modifies that range by extending the boundaries above and below the numerical values set forth. In general, the term “about” is used herein to modify a numerical value above and below the stated value by a variance of 10%. In one aspect, the term “about” means plus or minus 10% of the numerical value of the number with which it is being used. Therefore, about 50% means in the range of 45%⁻⁵⁵%. Numerical ranges recited herein by endpoints include all numbers and fractions subsumed within that range (e.g., 1 to 5 includes 1, 1.5, 2, 2.75, 3, 3.90, 4, 4.24, and 5).

Similarly, numerical ranges recited herein by endpoints include subranges subsumed within that range (e.g., 1 to 5 includes 1-1.5, 1.5-2, 2-2.75, 2.75-3, 3-3.90, 3.90-4, 4-4.24, 4.24-5, 2-5, 3-5, 1-4, and 2-4). It is also to be understood that all numbers and fractions thereof are presumed to be modified by the term “about.”

The following patents, applications, and publications as listed below and throughout this document are hereby incorporated by reference in their entirety herein.
[1]D. L. Young, K. Chen, S. Theingi, V. Lasalvia, D. Diercks, H. Guthrey, W. Nemeth, M. Page, and P. Stradins, “Reactive ion etched, self-aligned, selective area poly-Si/SiO₂ passivated contacts,” Solar Energy Materials and Solar Cells, vol. 217, p. 110621, 2020, doi: 10.1016/j.solmat.2020.110621.
[2]T. Dullweber, M. St&ouml; hr, C. Kruse, F. Haase, M. Rudolph, B. Beier, P. J&auml; ger, V. Mertens, R. Peibst, and R. Brendel, “Evolutionary PERC+ solar cell efficiency projection towards 24% evaluating shadow-mask-deposited poly-Si fingers below the Ag front contact as next improvement step,” Solar Energy Materials and Solar Cells, vol. 212, p. 110586, 2020, doi: 10.1016/j.solmat.2020.110586.
[3]A. Ingenito, G. Limodio, P. Procel, G. Yang, H. Dijkslag, O. Isabella, and M. Zeman, “Silicon Solar Cell Architecture with Front Selective and Rear Full Area Ion-Implanted Passivating Contacts,” Solar RRL, vol. 1, no. 7, p. 1700040, 2017, doi: 10.1002/solr.201700040.
[4]S. Dasgupta et al., “Novel Process for Screen-Printed Selective Area Front Polysilicon Contacts for TOPCon Cells Using Laser Oxidation,” IEEE J. Photovoltaics, vol. 12, no. 6, pp. 1282-1288, November 2022, doi: 10.1109/JPHOTOV.2022.3196822.
[5]R. A. Sinton, A. Cuevas, and M. Stuckings, Quasi-steady-state photoconductance, a new method for solar cell material and device characterization, 1996, pp. 457-460.
[6]A. Fell, “A Free and Fast Three-Dimensional/Two-Dimensional Solar Cell Simulator Featuring Conductive Boundary and Quasi-Neutrality Approximations,” IEEE Transactions on Electron Devices, vol. 60, no. 2, pp. 733-738, 2013.
[7]Y.-Y. Huang, A. Jain, W.-J. Choi, K. Madani, Y.-W. Ok, and A. Rohatgi, “Modeling and Understanding of Rear Junction Double-Side Passivated Contact Solar Cells with Selective Area TOPCon on Front,” in 2021 IEEE 48th Photovoltaic Specialists Conference (PVSC), June 2021, pp. 1971-1976, doi: 10.1109/PVSC43889.2021.9518628.
[8]K. Chen et al., “Self-Aligned Selective Area Front Contacts on Poly —Si/SiOₓ Passivating Contact c-Si Solar Cells,” IEEE J. Photovoltaics, vol. 12, no. 3, pp. 678-689, May 2022, doi: 10.1109/JPHOTOV.2022.3148719.
[9]A. Ingenito et al., “Silicon Solar Cell Architecture with Front Selective and Rear Full Area Ion-Implanted Passivating Contacts,” Sol. RRL, vol. 1, no. 7, p. 1700040, 2017, doi: 10.1002/solr.201700040.
[10] ITRPV, “International Technology Roadmap for Photovoltaic 2022,” 2022.
[11]M. A. Green et al., “Solar cell efficiency tables (Version 60),” Prog. Photovoltaics Res. Appl., vol. 30, no. 7, pp. 687-701, July 2022, doi: 10.1002/PIP.3595.
[12]S. W. Glunz et al., “Passivating and Carrier-selective Contacts—Basic Requirements and Implementation,” in 2017 IEEE 44th Photovoltaic Specialist Conference (PVSC), 25-30 Jun. 2017, pp. 2064-2069.

While various embodiments of the present invention have been described above, it should be understood that they have been presented by way of example only, and not limitation. It will be apparent to persons skilled in the relevant art that various changes in form and detail can be made therein without departing from the spirit and scope of the present invention. Thus, the breadth and scope of the present invention should not be limited by any of the above-described exemplary embodiments, but should be defined only in accordance with the following claims and their equivalents.

1.-59. (canceled)

60. A method of forming a double-sided (DS) tunnel oxide passivated contact (TOPCon) photovoltaic cell device comprising:
a) growing an intrinsic i-poly-Si on top of a tunnel oxide on a first (front) and a second (back) side of a substrate simultaneously;
b) depositing a boron doped glass on the second side of the substrate;
c) depositing an undoped silicon glass (USG) on the boron doped glass; and
d) simultaneously forming a n-TOPCon on the first side and a p-TOPCon on the second side of the substrate by a single step high temperature treatment comprising exposing the substrate formed in c) to (i) a first temperature for a first predefined time and then to (ii) a second temperature for a second predefined time.

61. The method of claim 60, wherein the substrate formed in step c) at the first temperature is exposed to a nitrogen gas for the first predetermined time, wherein the first temperature is 810° C.-950° C. and the first time is 30-60 min, thereby diffusing boron into poly-Si and forming the p-TOPCon on the second side of the substrate.

62. The method of claim 61, exposing the substrate to a POCl₃ at the second temperature for the second predefined time, wherein the second temperature is 840° C.-950° C. and the second predefined time is 30 min, thereby diffusing phosphorus into poly-Si and forming the n-TOPCon on the first side of the substrate.

63. The method of claim 60, wherein the first side is textured or planar.

64. The method of claim 60, wherein the method further comprises forming an asymmetric thickness DS TOPCon by exposing the substrate formed in step d) to an etch solution configured to etch the n-TOPCon at a higher rate than the p-TOPCon for a third time sufficient to obtain a first thickness of n-TOPCon and a second thickness of the p-TOPCon, wherein the first thickness is smaller than the second thickness.

65. The method of claim 64, wherein the first thickness is 20 nm and the second thickness is 100-200 nm, and wherein the third time is 2 min.

66. The method of claim 64, further comprising depositing a dielectric material on the n-TOPCon and/or p-TOPCon.

67. The method of claim 66, further comprising forming ohmic contacts on the first and/or second side of the DS TOPCon photovoltaic cell device.

68. The method of claim 64, further comprising forming a back junction double side TOPCon cell architecture.

69. The method of claim 68, wherein the back junction double side TOPCon cell architecture exhibits a metalized recombination current density (J₀) of ≤10 fA/cm².

70. The method of claim 60, further comprising:
selectively etching the n-TOPCon formed in step d) by
a) exposing the n-TOPCon to an ultraviolet source in a predetermined pattern to form a masked portion; and
b) etching a non-mask portion to form a patterned portion of the n-TOPCon.

71. The method of claim 70, wherein the patterned portion of the n-TOPCon is less than or equal to 5% of the n-TOPCon formed in step d).

72. The method of claim 70, wherein a thickness of the n-TOPCon and p-TOPCon is substantially the same.

73. The method of claim 70, wherein the ultraviolet source is a laser.

74. The method of claim 70, further comprising deposing a dielectric material on the patterned portion of the n-TOPCon.

75. The method of claim 74, further comprising forming metal contacts on the patterned portion of the n-TOPCon.

76. The method of claim 70, further comprising forming a back junction double side TOPCon cell architecture.

77. The method of claim 76, wherein the back junction double side TOPCon cell architecture exhibits a metalized recombination current density (J₀) of ≤10 fA/cm².

78. An apparatus comprising:
a tunnel oxide passivated contact (TOPCon) photovoltaic cell device which is a double-sided (DS) TOPCon that comprises:
a substrate having a first side and a second side;
a first tunnel oxide selective passivating contact on the first side of the substrate comprising a n-doped poly-Si/SiOₓ contact layer (n-TOPCon); and
a second tunnel oxide selective passivating contact on the second side of the substrate comprising a p-doped poly-Si/SiOₓ contact layer (p-TOPCon);
wherein the n and p-doped poly-Si/SiOₓ contact layers have metalized recombination current density (J₀) of ≤10 fA/cm², and wherein
the n and p-doped poly-Si/SiOₓ contact layers are simultaneously formed in a single high-temperature treatment.

79. The apparatus of claim 78, wherein the n-doped poly-Si/SiOₓ contact layer has a thickness of 20 nm and the p-doped poly-Si/SiOₓ contact layer has a thickness of 100-200 nm.

80. The apparatus of claim 78, wherein the n-doped poly-Si/SiOₓ contact layer has a thickness of 100-200 nm and the p-doped poly-Si/SiOₓ contact layer has a thickness of 100-200 nm, and wherein the n-doped poly-Si/SiOₓ contact layer is selectively etched to cover less than or equal to 5% of the first side of the substrate.

81. The apparatus of claim 80, further comprising a metal grid deposited on the n-doped poly-Si/SiOₓ contact layer and wherein a remaining area on the first side has an undiffused Si wafer passivated with a dielectric such that the device exhibits no diffusion in between metal grid lines.
